(19) United States
(12) Patent Application Publication
(10) Pub. No.: US 2013/0126531 A1
(43) Pub. Date: May 23, 2013

(54) CASE FOR FOR ENCLOSING A PERSONAL ELECTRONIC DEVICE

(71) Applicant: Speculative Product Design, LLC, Mountain View, CA (US)

(72) Inventors: Bryan Lee Hynecek, Redwood City, CA (US); Arthur Wu, San Francisco, CA (US); David Lean, San Francisco, CA (US)

(73) Assignee: Speculative Product Design, LLC, Mountain View, CA (US)

(21) Appl. No.: 13/678,446

(22) Filed: Nov. 15, 2012

Related U.S. Application Data
(60) Provisional application No. 61/563,485, filed on Nov. 23, 2011.

(51) Int. Cl. H05K 5/02

(52) U.S. Cl. CPC H05K 5/0217
USPC 220/315

(57) ABSTRACT

The present invention relates to protective cases for an electronic device that comprises an ejector mechanism. The protective case has an inner portion that receives the electronic device and an outer portion that the inner portion slides into when the ejector mechanism is transitioned from a first position to a second position.

### CROSS-REFERENCE

The present application claims the benefit of U.S. Provisional Application No. 61/563,485 filed 23 Nov. 2011; which is incorporated herein by reference in its entirety.

### BACKGROUND

1. Field of the Invention

The present invention relates generally to protective cases for an electronic device and specifically to protective case having a mechanism which aides with insertion and removal of the electronic device.

2. Description of the Background

Mobile phones, smart phones, tablet computers, personal readers, personal electronic assistants, MP3 players as well as other portable electronic devices are widely used and have become a ubiquitous part of every day life. Such devices, although designed to be used in real world environments, often contain sensitive electronics and are subject to damage if dropped from a normal operating position. Despite attempts to design these complicated electronic devices for real world application, it is often necessary to utilize some form of protective case to shield and protect the electronic devices from damage due to drops or falls.

Many different types and designs of cases exist and provide a wide range of protection. Cases may range from purely decorative to utilitarian, from soft pliable cases, to co-molded soft and hard cases to rigid cases. Soft case tend to provide less protection than rigid cases but are easy to use and easy to install on an electronic device. Co-molded soft and hard cases such as the CandyShell cases from Speculative Products may provide both ease of installation as well as superior case protection. Rigid cases provide maximum protection, but due to the nature of the rigid materials it is often hard or not possible to insert the electronic device into a case molded from a single piece. Accordingly, most rigid cases often composed of multiple parts such as a front and back or top and bottom which may increase their size. They often need to be snapped together and assembled around the device to form a rigid shell for the device. Likewise, they often are hard to open and separate when it becomes necessary to remove the electronic device from the case. Such repetitive opening and closing of the rigid parts may result in wear or breakage to the case itself.

It is therefore desirable to have a rigid case that is easy to open and close, provides superior protection and allows for easy insertion and removal of an electronic device without the need to snap and/or press fit the component pieces together. An embodiment of the present application discloses such a device.

The present disclosure provides for a case that protects an enclosed personal electronic device and is easy to operate because it facilitates easy insertion and/or removal of a personal electronic device from the case. It also provides for a case that has a slim profile and adds little exterior bulk to an inserted personal electronic device.

### SUMMARY

The teachings disclosed herein relate to protective cases for electronic devices. More particularly, the present teaching relate to protective cases having a mechanism which aides with insertion and removal of the electronic device.

In one example, a case for enclosing a personal electronic device is disclosed the case comprising a housing shaped to accept insertion of the personal electronic device and an ejection mechanism, configured such that when the ejection mechanism is arranged in a first position, a portion of the housing is open thereby enabling insertion of the personal electronic device into the housing and when the ejection mechanism is arranged in a second position, the portion of the housing is closed, thereby enclosing the personal electronic device in the housing.

In an embodiment, the ejection mechanism comprises a lever and a hinge that enable transition between the first and second positions of the ejection mechanism. In another embodiment, the hinge is a bent-arm hinge. In another embodiment, the ejection mechanism collapses into an approximately flat surface in parallel with a back surface of the housing when arranged in the second position. Alternatively, in an embodiment, the ejection mechanism is a sliding mechanism. In still another embodiment, the ejection mechanism comprises a gear and tooth or rack and pinion slider mechanism, that when rotated from a first position to a second position causes the first and second portions to separate. In an embodiment, the gear is connected to a dial that is co-planer with the back of the case. In other embodiments, the ejection mechanism may be a latch system over the center mechanism, a cam closure system, a spring latch with a push button release, a flexible push rod closure system, or a magnetic closure system.

In still another embodiment, a portion of the housing is attached to the housing by a flexible interface that extends from a back portion of the housing. In an embodiment, the flexible interface collapses into the housing when the ejection mechanism is in the second position.

In an embodiment, the housing is comprised of at least one of plastic, rubber, silicon, metal, a polycarbonate material, and a para-aramid material. In another embodiment, the housing is comprised of a plurality of layers of different materials.

An alternate embodiment discloses a case for a personal electronic device comprising an inner housing including a fitted cavity shaped to accept insertion of the personal electronic device, the inner housing comprising a first portion and a second portion joined by a flexible interface and a chassis shaped to cover the first portion of the inner housing, the chassis including an extension mechanism for extending the second portion of the inner housing from a closed position to an open position, such that the personal electronic device can be removed from or inserted into the inner housing when the second portion of the inner housing is in the open position and the personal electronic device can be enclosed within the inner housing when the extension mechanism is in the closed position. In an alternate embodiment, the case further comprises a flexible layer affixed to at least a portion of the inner housing or the chassis. The case may have an opening and closing of the mechanism that is controlled by a lever or another mechanism such as a gear and tooth or rack and pinion. In still another embodiment, the case comprises a screen over a window in the chassis, wherein the window aligns with an interface of the personal electronic device and enables the user to interact with the interface of the personal electronic device.

Additional advantages and novel features will be set forth in part in the description which follows, and in part will become apparent to those skilled in the art upon examination of the following and the accompanying drawings or may be learned by production or operation of the examples. The advantages of the present teachings may be realized and attained by practice or use of various aspects of the methodologies, instrumentalities and combinations set forth in the detailed examples discussed below.

### BRIEF DESCRIPTION OF THE DRAWINGS

The present application is illustrated by way of example, and not limitation, in the Figures of the accompanying drawings, in which:

FIG. 1A depicts a top perspective view of an inner housing, in accordance with an embodiment of the present disclosure;

FIG. 1B depicts a top plan view of an inner housing, in accordance with some embodiments of the present disclosure;

FIG. 1C depicts a top perspective view of an inner housing with an over-molded flexible layer, in accordance with some embodiments of the present disclosure;

FIG. 1D depicts a top plan view of an inner housing with an over-molded flexible layer, in accordance with some embodiments of the present disclosure;

FIG. 2A depicts a top perspective view of a chassis, in accordance with some embodiments of the present disclosure;

FIG. 2B depicts a top plan view of a chassis, in accordance with some embodiments of the present disclosure;

FIG. 2C depicts a top perspective view of a chassis with an over-molded flexible layer, in accordance with some embodiments of the present disclosure;

FIG. 2D depicts a top plan view of a chassis with an over-molded flexible layer, in accordance with some embodiments of the present disclosure;

FIG. 3 depicts a top perspective view of a case for a first portion of an inner housing, in accordance with some embodiments of the present disclosure;

FIGS. 4A-4I depict a view of the various components of a case, in accordance with an embodiments of the present disclosure;

FIG. 5 depicts the steps in an exemplary assembly process for a case, in accordance with some embodiments of the present disclosure;

FIGS. 6A-6F depict different views of an exemplary assembled case, in accordance with some embodiments of the present disclosure;

FIGS. 7A-D depict various cross-sectional views of exemplary assembled case, in accordance with some embodiments of the present disclosure;

FIGS. 8A-8F depict a series of photographs of an exemplary assembled case and components thereof, in accordance with some embodiments of the present disclosure;

FIGS. 9-12 depict a case in accordance with an embodiment of the present disclosure during the different phases of operating/opening the case;

FIG. 13 depicts an embodiment of an ejector mechanism in accordance with an embodiment of the present disclosure;

FIG. 14A depicts an exemplary chassis of a case with a flexible mechanism in accordance with an embodiment of the present disclosure;

FIG. 14B depicts a side view of a case with a second portion extending there from in accordance with an embodiment of the present disclosure;

FIG. 14C depicts the back of a case that shows an ejection mechanism and a second portion separated from first portion in accordance with an embodiment of the present disclosure;

FIG. 15 depicts an exemplary cover that may be attached to inner housing in accordance with an embodiment of the present disclosure;

FIG. 16 depicts an exemplary case including a first portion separated from a second portion that may be joined together via a clip or attachment mechanism in accordance with an embodiment of the present disclosure;

FIG. 17 depicts an exemplary case including an ejection mechanism in accordance with an embodiment of the present disclosure;

FIG. 18 depicts an exemplary case including an ejection mechanism in accordance with an embodiment of the present disclosure;

FIG. 19 depicts an embodiment of an exemplary case in accordance with an embodiment of the present disclosure;

FIG. 20 depicts a perspective view of a front of a case in accordance with an embodiment of the present disclosure;

FIG. 21 depicts a perspective view of the inner slider portion of a case in accordance with an embodiment of the present disclosure;

FIG. 22 depicts a cut away view of the case of FIG. 19 in accordance with an embodiment of the present disclosure;

FIGS. 23A-B depict finger dials and gears, respectively used in a case in accordance with an embodiment of the present disclosure, and

FIGS. 24A-D depicts an exemplary operation of a case in accordance with the present disclosure.

Throughout the drawings, the same reference numerals and characters, unless otherwise stated, are used to denote like features, elements, components, or portions of the illustrated embodiments. Moreover, while the subject invention will now be described in detail with reference to the drawings, the description is done in connection with the illustrative embodiments. It is intended that changes and modifications can be made to the described embodiments without departing from the true scope and spirit of the subject invention as defined by the appended claims.

### DETAILED DESCRIPTION

Described herein are exemplary cases for enclosing a personal electronic device, such as, a mobile phone, a tablet computer, and e-book reader, or a personal digital assistant (PDA). In most instances, the exemplary cases disclosed herein include an inner housing that is inserted into or is otherwise affixed to an exterior chassis. Portions of the inner housing and/or chassis maybe over-molded with one or more materials.

Embodiments of the cases disclosed herein may be fabricated via any appropriate fabrication process including, but not limited to, injection molding, injection over molding, over molding, cutting, die cutting, and utilization of means to affix one component of an exemplary case to another component of the exemplary case. Embodiments of the cases disclosed herein may be fabricated from any appropriate material including, but not limited to, plastic, rubber, silicone, metal, fabric, a polycarbonate material, and a para-aramid material and may be manufactured in a variety of colors, patterns, and/or finishes.

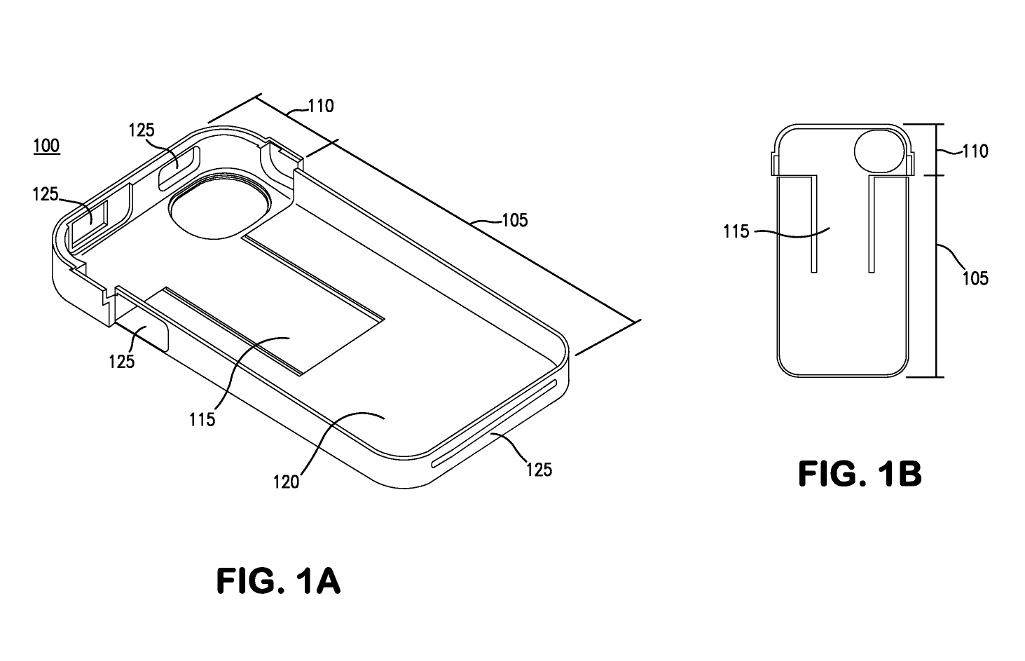

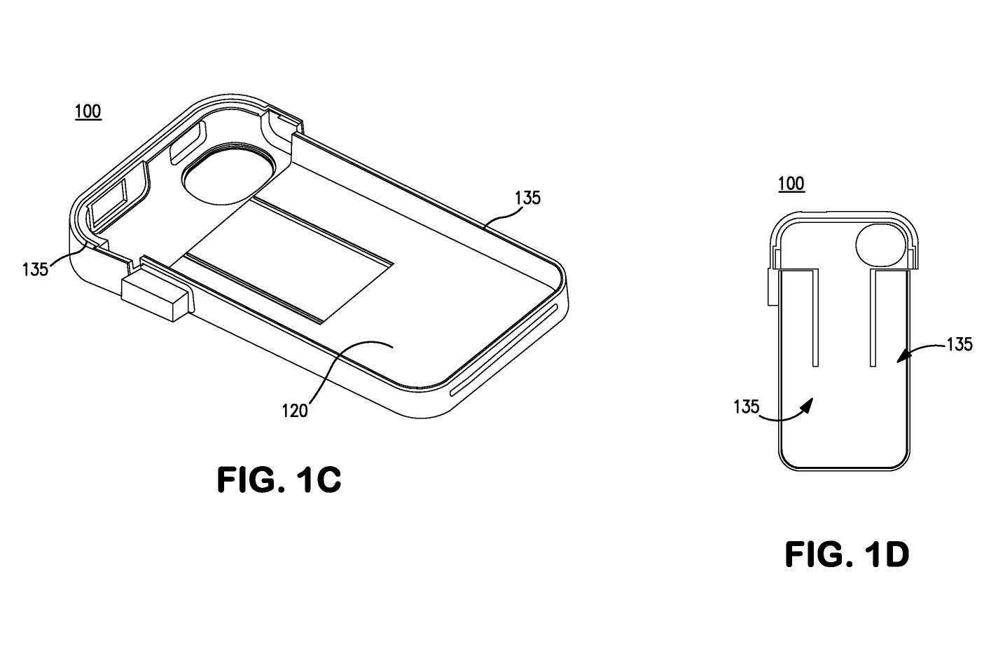

An embodiment of the present invention may be made up of an inner housing 100, chassis 200, cover 300, and ejection mechanism 400. FIGS. 1A and 1B depict different views of an exemplary inner housing 100 portion of a case for enclosing a personal electronic device. Exemplary inner housing 100 includes a first portion 105, a second portion 110, a flexible interface 115, a fitted cavity 120, and a plurality of apertures 125. Fitted cavity 120 may be sized and shaped to accept an inserted personal electronic device and may cover a portion of the back and/or side surfaces of the inserted personal electronic device.

When an inserted personal electronic device is oriented vertically, first portion 105 may cover a bottom portion of the inserted personal electronic device and second portion 110 may cover a top portion of the inserted personal electronic device. Of course, a reverse orientation of first portion 105 and second portion 110 with regard to the inserted personal electronic device may also be possible.

Flexible interface 115 may join first portion 105 to second portion 110 and may be flexible enough to enable second portion 110 to be positioned at an angle above and/or below first portion 105. In some embodiments, flexible interface 115 may collapse and/or extend and thereby enable separation of second portion 110 from first portion 105. Although FIGS. 1A and 1B indicate flexible interface 115 is fabricated from the same material as first and second portions 105, 110, flexible interface 115 may be fabricated from a separate material and then joined or affixed to first portion 105 and/or second portion 110 using any known means such as heat welding, mechanical attachment, glue or other chemical bonding.

Apertures 125 may be openings or other interfaces that enable a user to access and/or communicate with a feature provided by the inserted personal electronic device. Apertures 125 may be sized, shaped, and/or positioned to accommodate one or more features provided by the inserted personal electronic device, such as interface ports, microphones, speakers, and/or buttons.

FIGS. 1C-1D depict different views of inner housing 100 over-molded with a flexible layer 135. In some embodiments, flexible layer 135 may be manufactured from a silicon or plastic material, such as thermoplastic polyurethane (TPU). Flexible layer 135 maybe over-molded onto, for example, an interior surface of fitted cavity 120 and/or an exterior surface of the second portion 110.

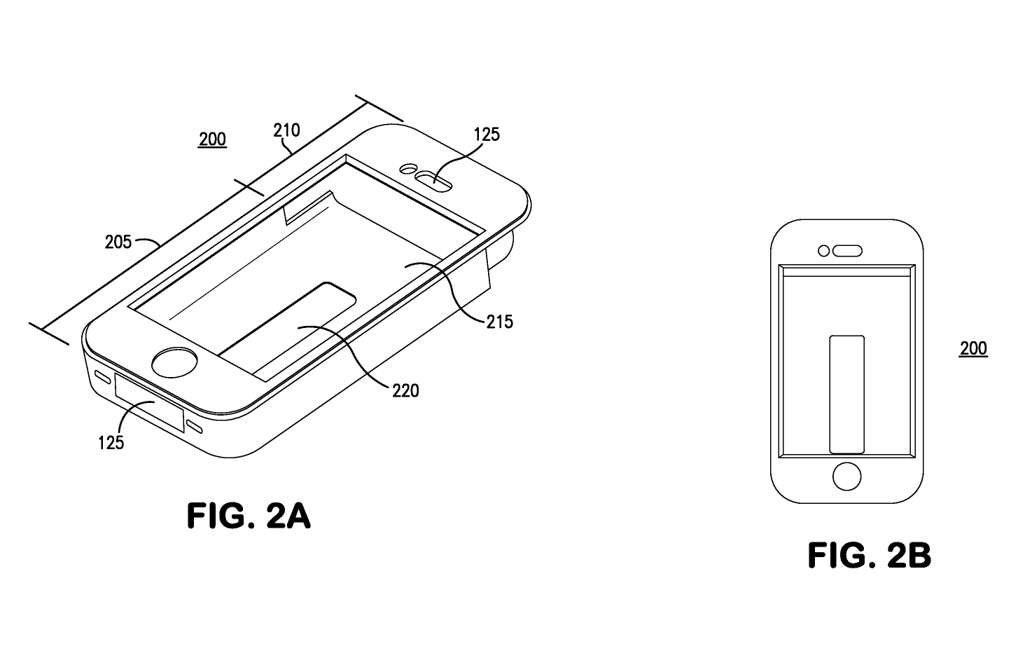

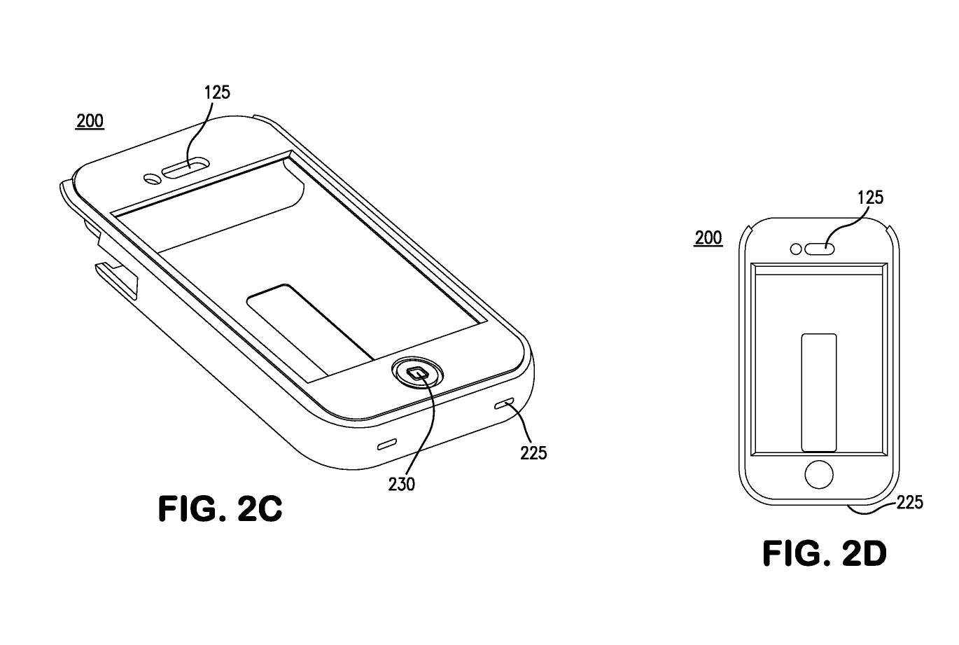

FIGS. 2A-2B depict different views of a chassis 200. Chassis 200 may comprise an external portion of cases disclosed herein. Chassis 200 may include a first portion 205, a second portion 210, a fitted cavity 215, an ejection mechanism aperture 220, and a plurality of apertures 125. In some embodiments, chassis 200 may be sized and shaped to accommodate insertion of inner housing 100. Chassis first portion 205 may correspond to inner housing first portion 105. Likewise, chassis second portion 210 may correspond to inner housing second portion 210. In some embodiments, chassis second portion 210 may be open so as to accommodate insertion of inner housing first portion 110 and/or areas of first portion 110 over-molded with flexible layer 135.

Ejection mechanism aperture 220 may be sized and shaped to accommodate an ejection mechanism 400. Chassis 200 may be fabricated via an injection molding process using a molds or any other manufacturing process. FIG. 2B depicts a top plan view of chassis 200 in accordance with an embodiment of the present disclosure.

FIGS. 2C and 2D depict different views of chassis 200 over-molded with a flexible layer 225. In some embodiments, flexible layer 225 may be manufactured from a silicon or plastic material, such as TPU. Flexible layer 225 maybe over-molded onto, for example, an exterior surface of, for example, the sides of chassis 200. Chassis 200 may also include an over-molded button 230.

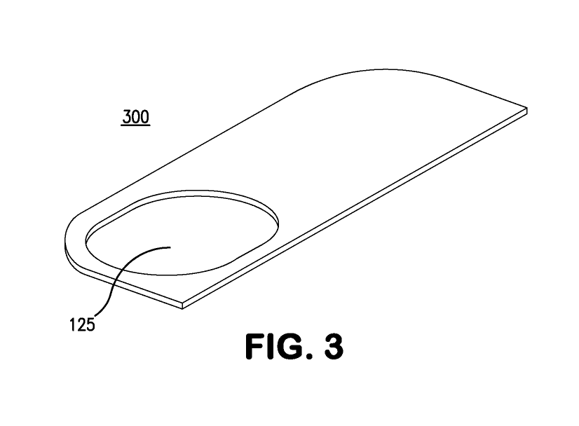

FIG. 3 depict a perspective views of a cover 300 that may be affixed to an exterior surface of inner housing second portion 110 and, in some cases, may be manufactured from the material used to manufacture chassis 200. Cover 300 may include one or more apertures 125 and may be fabricated via any known molding process. Cover 300 may be affixed to inner housing 110 via any conventionally available means.

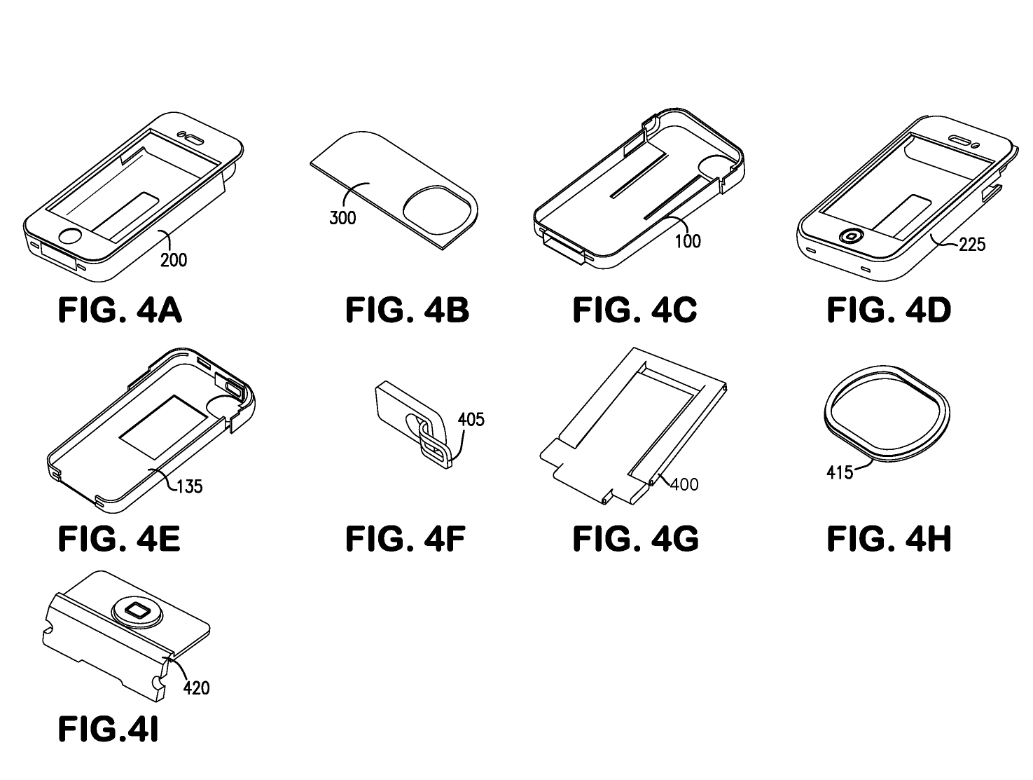

FIGS. 4A-4J depict an exploded view of a case of an embodiment of the present disclosure. FIG. 4A depicts chassis 200. FIG. 4B depicts cover 300. FIG. 4C depicts inner housing 100. FIG. 4D depicts flexible layer 225. FIG. 4E depicts flexible layer 135. FIG. 4F depicts an optional headphone door 405 that may be included in the case. FIG. 4G depicts an exemplary ejection mechanism 400. FIG. 4H depicts an optional camera flash ring 415 and FIG. 4I depicts an optional bottom door/button cover 420 that may be included in the case.

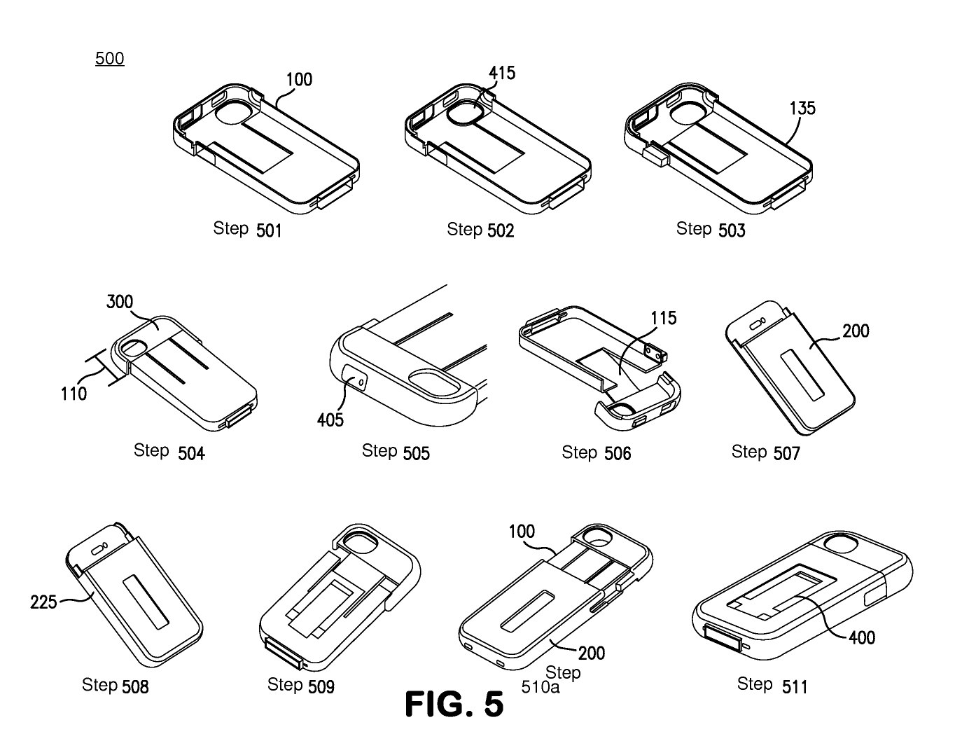

FIG. 5 depicts an exemplary assembly process 500 for assembling an exemplary case 510. Process 500 begins with the fabrication and/or molding of inner housing 100 (step 501). In step 502, camera flash ring 415 is inserted into the inner housing 100. Inner housing 100 is then over-molded with flexible layer 135 (step 503). Next, cover 300 is affixed to the exterior of inner housing second portion 110 (step 504) and headphone door 405 is assembled and inserted into inner housing 100 (step 505). Then, in step 506, flexible interface 115 is bent or otherwise modified in order to, for example, create a flexible joint and/or spring.

In step 507, chassis 200 is fabricated and/or molded and in step 508, chassis 200 is over-molded with flexible layer 225. At this point, inner housing 100 as seen in step 509 is inserted into fitted cavity 215 of chassis 200 (step 510a) and the ejection mechanism 400 is installed into exemplary case 510 at step 511.

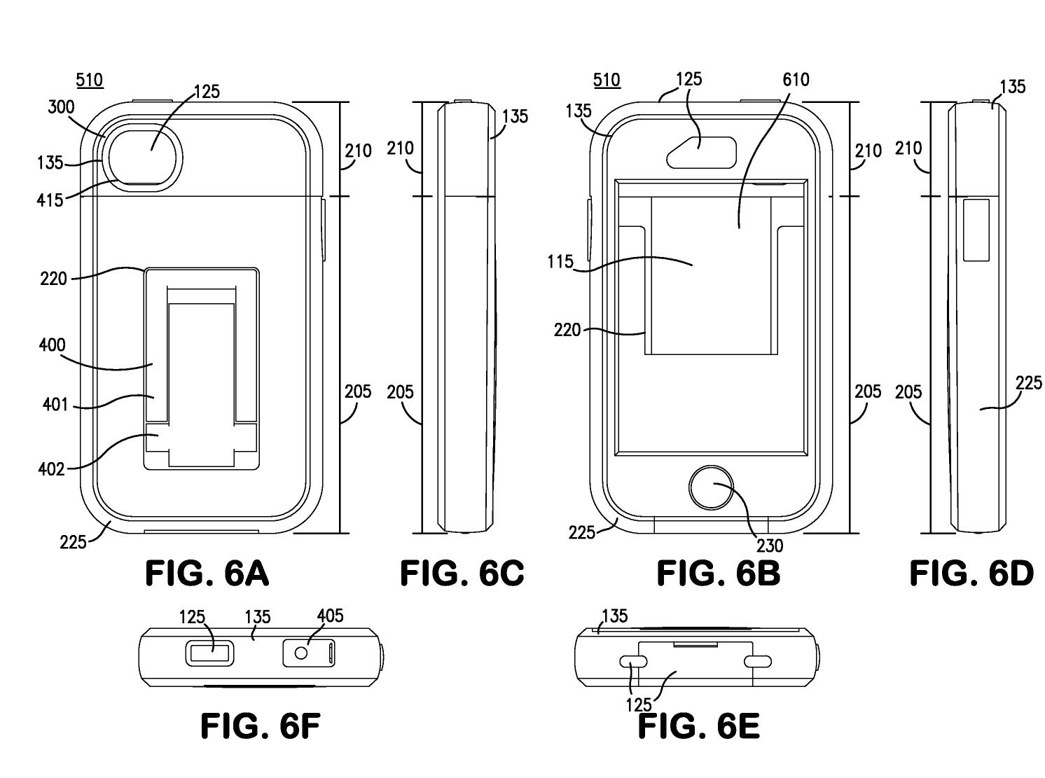

FIGS. 6A-6F depict different views of an exemplary assembled case 510. FIG. 6A depicts a rear plan view of the exemplary assembled case 510 and illustrates the placement of chassis first portion 205, chassis second portion 210, cover 300, inner housing flexible layer 135, chassis flexible layer 225, ejection mechanism aperture 220, ejection mechanism 400, optional camera flash ring 415, and an aperture 125.

FIG. 6B depicts a front plan view of the exemplary assembled case 510 and illustrates the placement of chassis first portion 205, chassis second portion 210, inner housing flexible layer 135, chassis flexible layer 225, flexible interface 115, over-molded button 230, ejection mechanism aperture 220, and an apertures 125.

Exemplary assembled case 510 also includes a window 610 via which a display or user interface may be accessed and/or viewed by a user of an enclosed personal electronic device. In some embodiments, some, or all, of window 610 may be covered by a screen that serves to protect a portion of the personal electronic device exposed by window 610. In many cases, the screen may be transparent or semi-transparent and may therefore enable the user to view and/or interface with the display and/or user interface while not changing an appearance of the user interface or data (e.g., images or text) provided by the display.

FIG. 6C depicts a first side view of exemplary assembled case 510 and illustrates the placement of chassis first portion 205, chassis second portion 210, inner housing flexible layer 135, and chassis flexible layer 225.

FIG. 6D depicts a second side view of exemplary assembled case 510 and illustrates the placement of chassis first portion 205, chassis second portion 210, inner housing flexible layer 135, and chassis flexible layer 225.

FIG. 6E depicts a bottom view of exemplary assembled case 510 and illustrates the placement of chassis flexible layer 225 and a plurality of apertures.

FIG. 6F top depicts a top view of exemplary assembled case 510 and illustrates the placement of inner housing flexible layer 135, aperture 125, and optional headphone door 405.

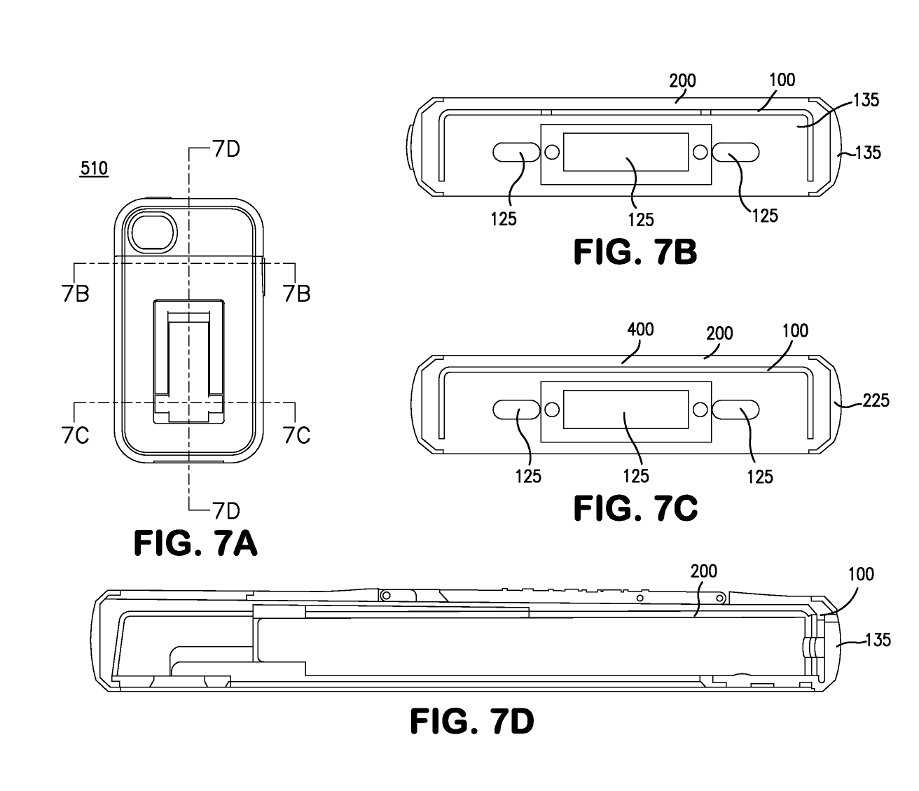

FIGS. 7A-D depict various cross-sectional views of exemplary assembled case 510. FIG. 7A depicts a top plan view of assembled case 510 bisected into three cross sections. FIG. 7B depicts a first horizontal cross section A-A of case 510 and illustrates placement of the components of inner housing second portion 110 and chassis second portion 210 including inner housing 100, inner housing over-molded flexible layers 135, chassis 200, and apertures 125.

FIG. 7C depicts a second horizontal cross section C-C of case 510 and illustrates placement of the components of inner housing first portion 105 and chassis first portion 205 including inner housing 100, chassis 200, chassis over-molded flexible layers 225, ejection mechanism 400, and apertures 125.

FIG. 7D depicts a vertical cross section B-B of exemplary assembled case 510 and illustrates the placement of inner housing 100, inner housing over-molded flexible layers 135, chassis 200, chassis over-molded flexible layers 225, and ejection mechanism 400 comprising lever or flipper pivot 401 and lever or flipper 402. As will be described with respect to other embodiments, ejection mechanism 400 is not limited to a lever or flipper or flipper pivot, but may be any other types of ejection mechanism that when activated causes the inner and outer housings to separate, allowing for insertion of a personal electronic device without having to dissemble the case. In an embodiment, the ejection mechanism may be a toothed gear that engages with a correspondingly toothed slider, creating a rack and pinion type mechanism that when rotated by a dial causes the first and second portions to separate. Similarly, the ejection mechanism, when engaged in the opposite direction causes the first and second portions to close. Additionally and/or alternatively, the ejection mechanism may comprise a latch system over the center mechanism, a cam closure system, a spring latch with a push button release, a flexible push rod closure system, or a magnetic closure system.

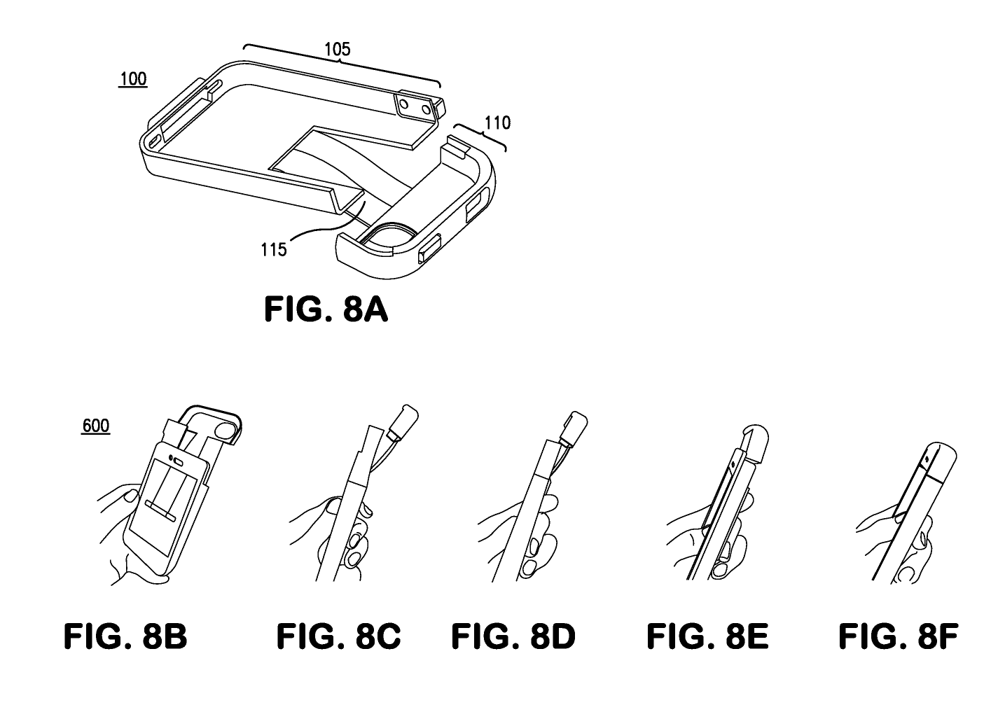

FIG. 8A depicts an embodiment of inner housing 100 showing flexible interface 115 bent or otherwise adjusted in order to separate inner housing first portion 105 from inner housing second portion 110 in this position, a personal device may be slid into fitted cavity 120.

FIGS. 8B-8F depict a series of photographs of a process 600 for ejecting or separating first portion 105 from second portion 110 of an exemplary case 510. FIG. 8B is a side perspective view and FIG. 8C is a side view of exemplary case 510 and depicts one exemplary way in which first portion 105 may be separated from second portion 110 via flexible interface 115.

While second portion 110 is separated from first portion 105 as shown in FIGS. 8B and 8C, a personal electronic device may be inserted into exemplary case 510 and/or a fitted cavity contained therein, such as fitted cavity 120. Once the personal electronic device is inserted into exemplary case 510, second portion 110/210 may be positioned or aligned such that it may be connected to first portion 105/205 as shown in FIGS. 8D and 8E. Second portion 110/210 may then be connected to first portion 105/205 as shown in FIG. 8F via, for example, ejection mechanism 400. On some occasions, the positioning of second portion 110/210 such that it may be connected to first portion 105/205 may be facilitated by the flexibility of flexible membrane 115 and the connection of second portion 110/210 to first portion 105/205 may be facilitated by a collapse or bending of flexible membrane 115 into inner housing 100, chassis 200, and/or some combination thereof.

In some embodiments, ejection mechanism 400, assembled case 510, and/or a component thereof may include an ejection mechanism feedback feature that indicates to a user when, for example, the ejection mechanism is open or closed. Exemplary feedback features include an auditory click, a visual indication (color or text), or tactile snapping or sealing sensation when ejection mechanism 400 is fully open, fully closed, or in-between.

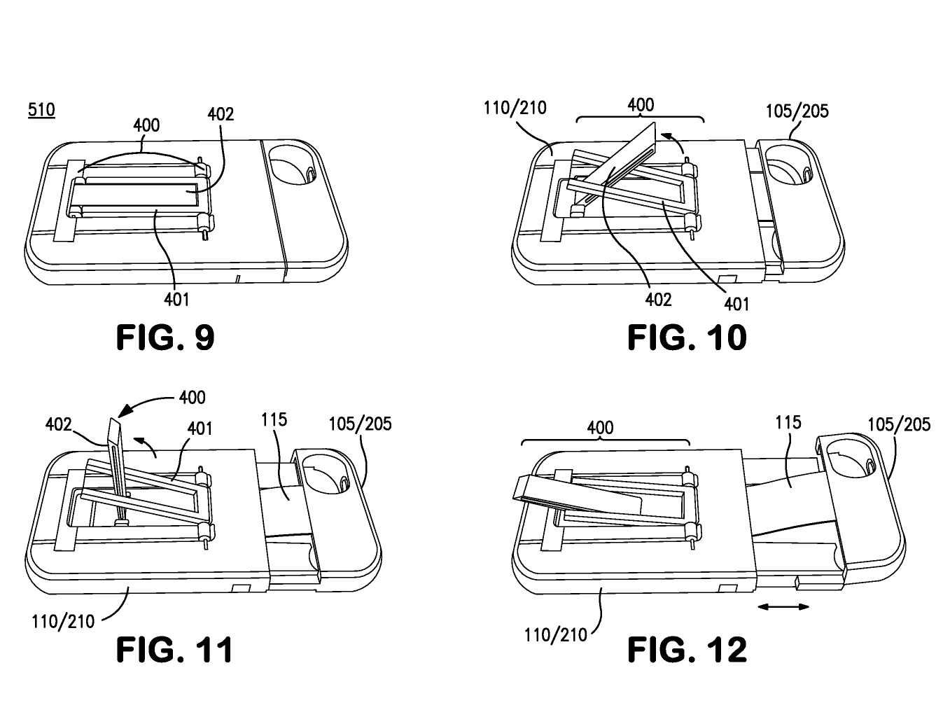

FIGS. 9-12 are photographs depicting a rear perspective view of an exemplary case 510 including an exemplary ejection mechanism 400 comprising flipper pivot 401 and flipper 402. In these figures, ejection mechanism 400 includes a hinged lever comprising flipper pivot 401 and flipper 402 in a closed position. While in the closed position, ejection mechanism 400 forms an approximately flat surface that is in parallel to a back surface of exemplary case 510. Other ejection mechanisms may be employed to open and close case 510. In one embodiment, a rack and pinion type mechanism, such as a toothed gear and toothed slider may be used. In still other embodiments, the ejection mechanism may be a latch system over the center mechanism, a cam closure system, a spring latch with a push button release, a flexible push rod closure system, or a magnetic closure system.

FIG. 10 depicts ejection mechanism 400 in a partially open position. The partial opening of ejection mechanism 400 pushes second portion 110/210 away from first portion 105/205 in a horizontal direction. The open position of ejection mechanism 400 depicted in FIG. 11 is further extended or opened and, consequently, second portion 110/210 has moved further away from first portion 105/205 in the horizontal direction.

FIG. 12 depicts ejection mechanism 400 in a fully open position. While ejection mechanism 400 is in the fully open position, second portion 110/210 moves still further away from first portion 105/205 in the horizontal direction and upward in a vertical direction. While in this position, a user may easily insert a personal electronic device into exemplary case 510. The personal electronic device may then be fully enclosed within exemplary case 510 by returning ejection mechanism 400 to its original position as depicted in FIG. 10 by, for example, reversing the process shown in FIGS. 10-12

Flipper pivot 401 and flipper 402 may be connected by pins clips or any other mechanical connection that allows flipper 402 to pivot on flipper pivot 401 thereby driving or forcing the first portion and second portion to separate. Other ejection mechanisms 400 may be used without departing from the spirit of the invention. Alternatively and/or additionally, ejection mechanism 400 may be a button slide, a single lever, a spring mechanism, a thumb wheel, a pinch and slide mechanism or any other ejector configuration that allows first portion 105/205 and second portion 110/220 to engage/disengage.

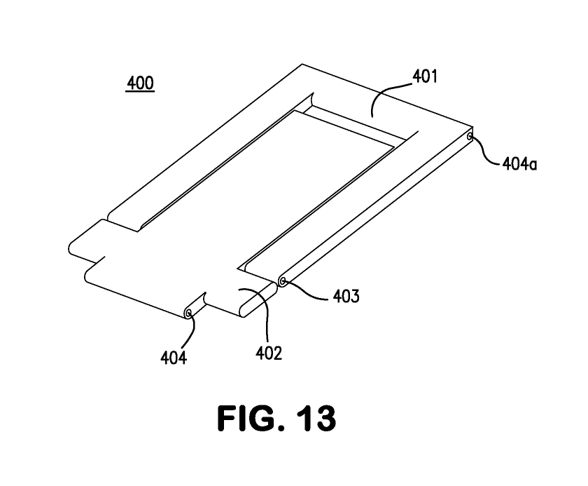

FIG. 13 depicts an embodiment of ejector mechanism 400 comprising flipper pivot 401, flipper 402 and pins 403, 404 and 404a. As seen in FIG. 13, flipper pivot 401 and flipper 402 are pinned together at pin 403 thereby creating a pivot point when flipper 402 is raised with respect to flipper pivot 401. Pin 404 may be used to anchor ejector mechanism 400 to inner housing 115 and pin 404a may be used to anchor the ejector mechanism to chassis 200.

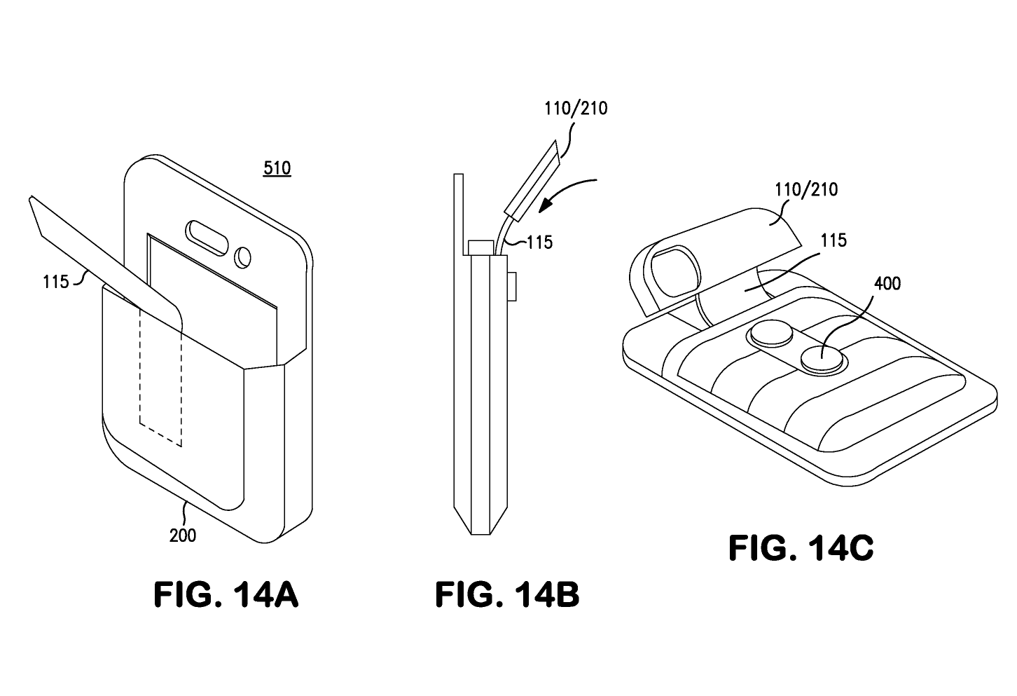

FIGS. 14-17 are drawings depicting various embodiments of exemplary cases 510. FIG. 14A depicts an exemplary chassis 200 with a flexible mechanism 115 extending therefrom. FIG. 14B depicts a side view of the embodiment of case 510 depicting second portion 110/210 extending from case 510. FIG. 14C depicts the back side of case 510 that shows ejection mechanism 400 and second portion 110/210 being separated from first portion 105/205 via a flexible mechanism 115. Ejector 400 may be comprise a series of gears or notches that engage similar gears and or notches, in a rack and pinion type configuration, that keep ejector mechanism 400 in position until it is slid or rotated by the user to eject second portion 110/210 from first portion 105/205.

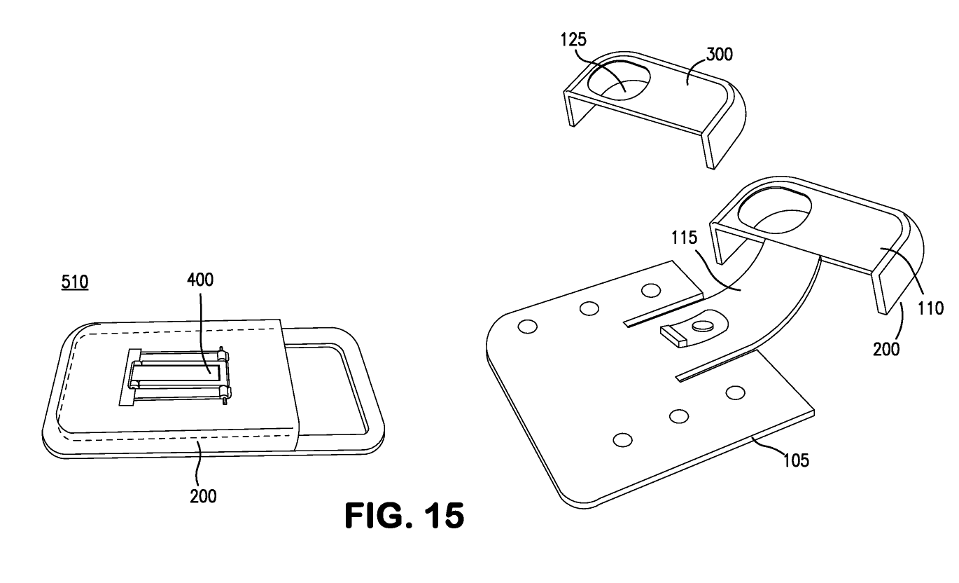

FIG. 15 depicts an exemplary cover 300 that may be attached to inner housing second portion 110. Inner housing 100 also includes first portion 105 and second portion 110 joined to one another via flexible mechanism 115. Inner housing 110 is shown as being inserted into chassis 200 and chassis 200 includes ejection mechanism 400.

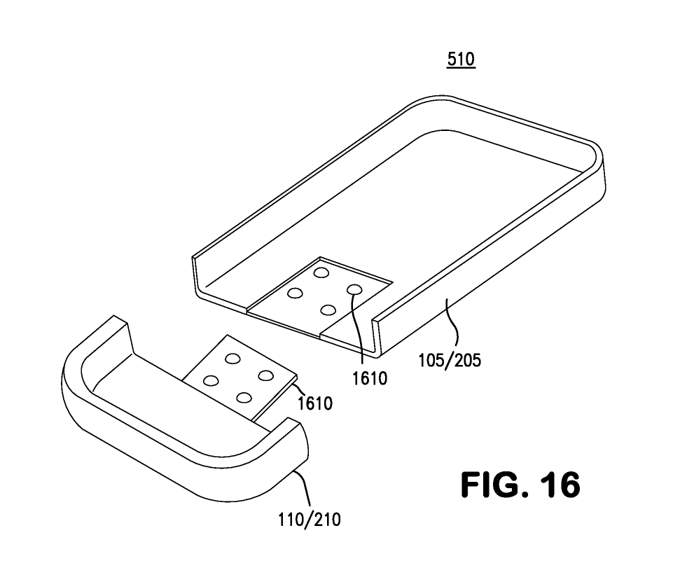

FIG. 16 depicts an exemplary case 510 including a first portion 105/205 separated from second portion 110/210 that may be joined together via a clip or attachment mechanism 1610. Attachment mechanism 1610 may be any form of ejectable release mechanism such as an interlocking clip of slide.

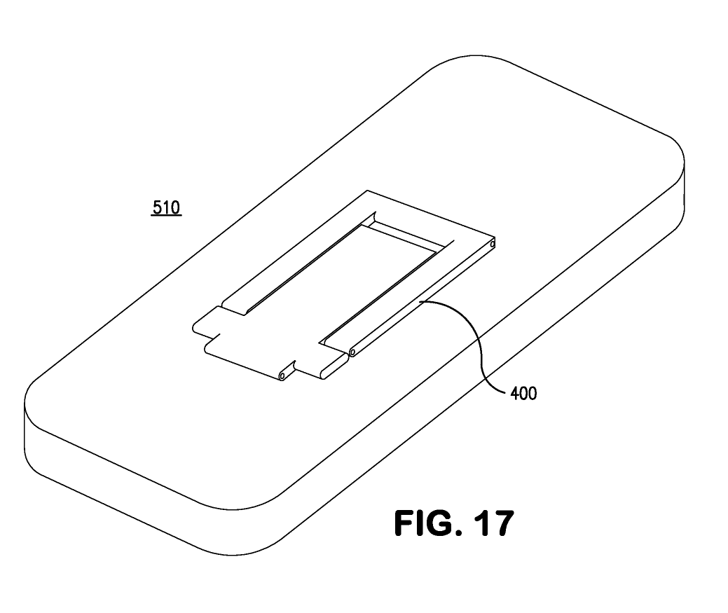

FIG. 17 depicts an exemplary case 510 including an ejection mechanism 400 which may be a slide, a spring loaded release or any other ejector mechanism that releases and/or retains the portions of case 510.

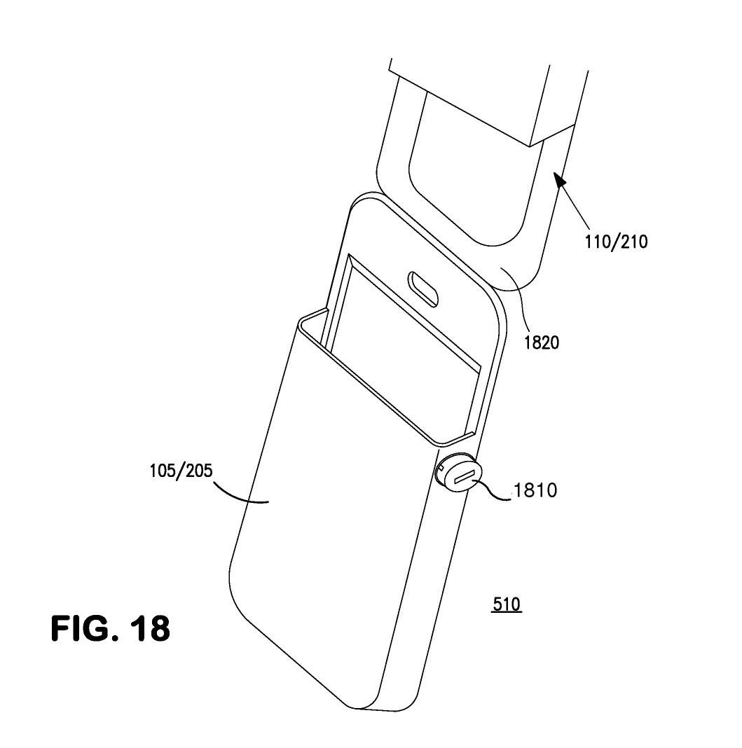

FIG. 18 depicts an exemplary case 510 including an ejection mechanism. The ejection mechanism may be comprised of a button or knob 1810 that may be rotated or depressed to eject second portion 110/210 from first portion 105/205. First portion 105/205 may be hingedly connected to second portion 110/210 by hinge 1820. Additionally, and/or alternatively, second portion 110/210 maybe ejected from case 510 upon the activation of ejector mechanism 400 creating access to fitted cavity 120 for insertion of a personal electronic device.

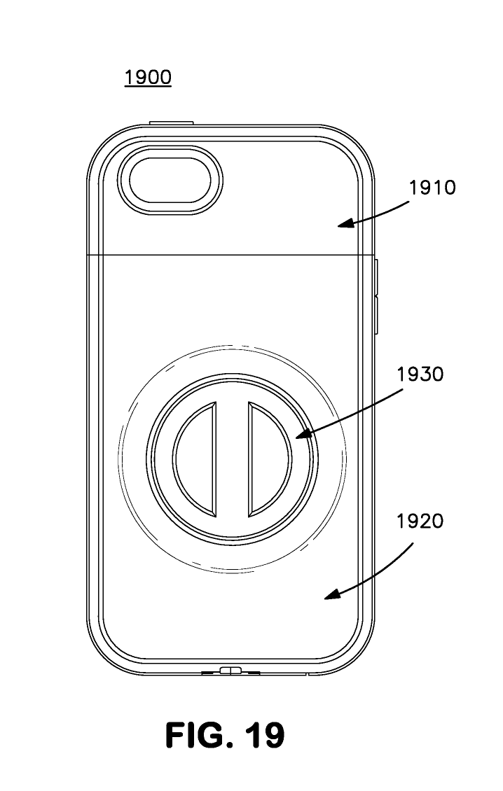

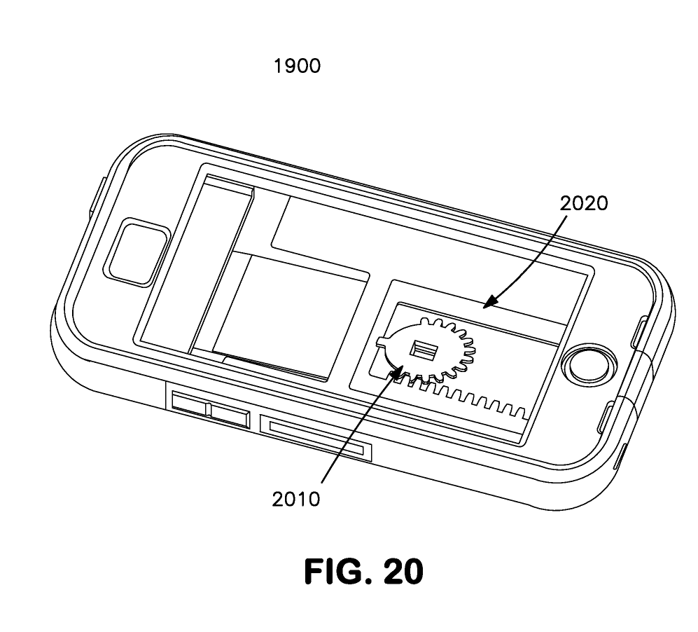

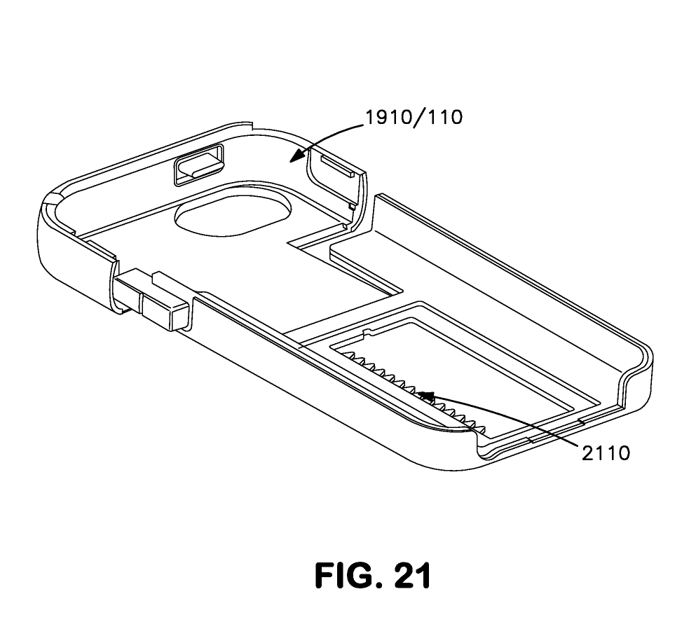

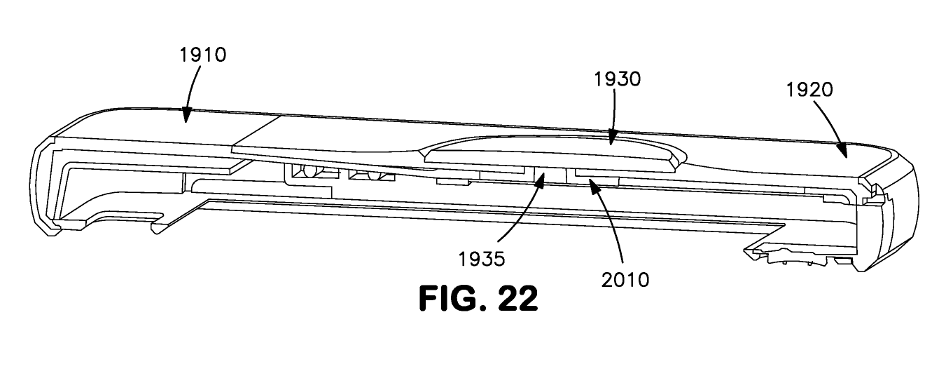

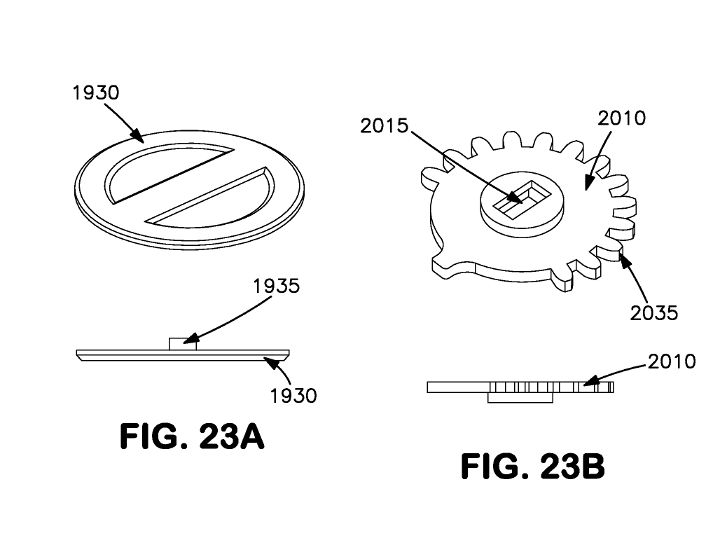

FIG. 19 depicts case 1900 which is an embodiment of the present disclosure. Case 1900 rather than containing a lever for the ejection mechanism 400, contains a rack and pinion or gear and tooth mechanism to separate the cases first portion from the second portion, such that case 1900 may be opened to insert a personal electronic device. As seen in FIG. 19, case 1900 comprises top portion 1910 which is comprised of the inner portion 1910/110 and outer or bottom portion 1920. Case 1900 also has dial 1930 which, when rotated by a user acts to engage the ejection mechanism to separate top portion 1910 from the bottom portion 1920. Dial 1930 may be fit into a recess in bottom portion 1920 so as to be co-planer with the surface of bottom portion 1920 or may be surface mounted on bottom portion 1920. Additionally and or alternatively, the back of case 1900 may be shaped and/or contoured to accept dial 1930 into its surface. Dial 1930, as seen in FIGS. 22 and 23 engages with gear 2010 through bottom surface 1920. Dial 1930 may have protrusion 1935 that engages with slot 2015 in gear 2010. Additionally and or alternatively, dial 1930 may be connected to gear 2010 by other means, such as adhesive, thermal bonding, molding or welding.

FIG. 20 depicts a view of the inside view of case 1900. Inner portion 1910/110 may contain slider portion 2020 which may be formed with teeth or notches 2110 to engage the teeth 2035 or notches of gear 2010. Rotation of gear 2010 by rotating dial 1930 causes teeth 2035 of gear 2010 to traverse teeth 2110 of slider 2020 causing the portions of the case 1900 to separate. Such a configuration of a gear and toothed slider may be known as a rack and pinion or other configuration. Such gear interaction causes inner portion 1910/110 to separate from bottom portion 1920 thereby causing case 1900 to open such that the personal electronic device may be inserted.

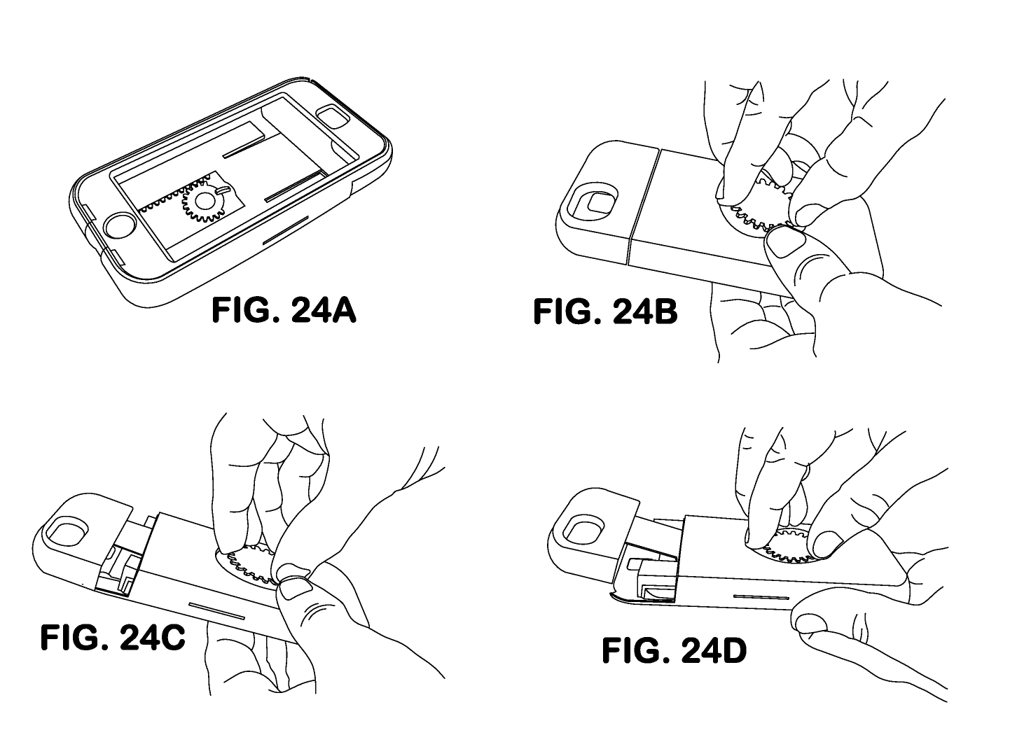

FIGS. 24A-D depict an exemplary case 1900 in operation. FIG. 24A shows the case 1900 containing gear 2010 in a closed position without a personal electronic device installed. It should be noted, that gear 2010 with teeth 2035 and slider 2020 with teeth 2110 may be covered with a Mylar or other suitable type material film (not shown), to protect the ejection mechanism. FIGS. 24B-C depicts the partial rotation of the ejection mechanism and the case in a partially open position. The partial opening of ejection mechanism 400 pushes bottom portion 1920 away from top portion 1910 in a horizontal direction. As dial 1930 is further rotated and gear 2010 slides further along slider 2020, the ejection mechanism moves bottom portion 1920 further away from top portion 1910 in the horizontal direction. FIG. 24D depicts the ejection mechanism in a fully rotated position. While the ejection mechanism is in a fully rotated position, bottom portion 1920 moves still further away from top portion 1910 in the horizontal direction and upward in a vertical direction due to the flexibility of interface 115. While in this position, a user may easily insert a personal electronic device into case 1900. The personal electronic device may then be fully enclosed within case 1900 by rotating dial 1930 in the opposite direction back to its original position, for example, reversing the process shown in FIGS. 24A-D.

In some embodiments, dial 1930 of the ejection mechanism and/or a component thereof may include an ejection mechanism feedback feature that indicates to a user when, for example, the ejection mechanism is open or closed. Exemplary feedback features include an auditory click, a visual indication (color or text), or tactile snapping or sealing sensation when dial 1930 is fully rotated or in-between.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

1. A case for enclosing a personal electronic device comprising:
a housing shaped to accept insertion of the personal electronic device; and
an ejection mechanism, configured such that when the ejection mechanism is arranged in a first position, a portion of the housing is open thereby enabling insertion of the personal electronic device into the housing and when the ejection mechanism is arranged in a second position, the portion of the housing is closed, thereby enclosing the personal electronic device in the housing.

2. The case of claim 1, wherein the ejection mechanism comprises a lever and a hinge that enable transition between the first and second positions of the ejection mechanism.

3. The case of claim 2, wherein the hinge is a bent-arm hinge.

4. The case of claim 1, wherein the ejection mechanism collapses into an approximately flat surface in parallel with a back surface of the housing when arranged in the second position.

5. The case of claim 1, wherein the ejection mechanism is a sliding mechanism.

6. The case of claim 1, wherein the portion of the housing is attached to the housing by a flexible interface that extends from a back portion of the housing.

7. The case of claim 1, wherein the flexible interface collapses into the housing when the ejection mechanism is in the second position.

8. The case of claim 1, wherein the housing is comprised of at least one of plastic, rubber, silicon, metal, a polycarbonate material, and a para-aramid material.

9. The case of claim 1, wherein the housing is comprised of a plurality of layers of different materials.

10. A case for a personal electronic device comprising:
an inner housing including a fitted cavity shaped to accept insertion of the personal electronic device, the inner housing comprising a first portion and a second portion joined by a flexible interface; and
a chassis shaped to cover the first portion of the inner housing, the chassis including an extension mechanism for extending the second portion of the inner housing from a closed position to an open position, such that the personal electronic device can be removed from or inserted into the inner housing when the second portion of the inner housing is in the open position and the personal electronic device can be enclosed within the inner housing when the extension mechanism is in the closed position.

11. The case of claim 10, further comprising:
a flexible layer affixed to at least a portion of the inner housing or the chassis.

12. The case of claim 10 wherein the opening and closing of the extension mechanism is controlled by a lever.

13. The case of claim 10 further comprising a screen over a window in the chassis,
wherein the window aligns with an interface of the personal electronic device and enables the user to interact with the interface of the personal electronic device.

14. The case of claim 1, wherein the ejection mechanism comprises a gear and toothed slider that enables transition between the first and second positions of the ejection mechanism.

15. The case of claim 1, wherein the ejection mechanism comprises a rack and pinion that enables transition between the first and second positions of the ejection mechanism.

16. The case of claim 14, wherein the gear is coupled to a rotatable dial that is approximately co-planer with a back surface of the housing.

17. The case of claim 10 wherein the opening and closing of the extension mechanism is controlled by a dial.

18. The case of claim 17 wherein the dial is coupled to a rack and pinion mechanism.

19. The case of claim 10 wherein the opening and closing of the extension mechanism is controlled by a gear.
